(19) United States
(12) Patent Application Publication
(10) Pub. No.: US 2010/0133586 A1
(43) Pub. Date: Jun. 3, 2010

(54) HETEROJUNCTION BIPOLAR TRANSISTOR AND METHOD OF FORMING THE SAME

(75) Inventors: Byoung-Gue MIN, Daejeon (KR); Jong-Min Lee, Daejeon (KR); Seong-II Kim, Daejeon (KR); Kyung-Ho Lee, Daejeon (KR); Hyung-Sup Yoon, Daejeon (KR); Eun-Soo Nam, Daejeon-si (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/463,011

(22) Filed: May 8, 2009

(30) Foreign Application Priority Data
Nov. 29, 2008 (KR) 2008-120193

(51) Int. Cl. H01L 29/737; H01L 21/331

(52) U.S. Cl. 257/197; 438/320; 257/E29.188; 257/E21.371

(57) ABSTRACT

Provided are a heterojunction bipolar transistor and a method of forming the same. The method includes forming an emitter electrode on an emitter capping pattern, a base electrode on a base pattern, and a collector electrode on a subcollector pattern, the subcollector pattern, the base pattern, an emitter pattern, and the emitter capping pattern being provided to a substrate; patterning a protection insulation layer and a first dummy pattern covering the emitter electrode, the base electrode, and the collector electrode, to expose the emitter electrode, the base electrode, and the collector electrode; forming a second dummy pattern to electrically separate the emitter electrode, the base electrode, and the collector electrode; forming, on the substrate provided with the second dummy pattern, an emitter electrode interconnection connected to the emitter electrode, a base electrode interconnection connected to the base electrode, and a collector electrode interconnection connected to the collector electrode; and removing the first and second dummy patterns.

### CROSS-REFERENCE TO RELATED APPLICATIONS

This U.S. non-provisional patent application claims priority under 35 U.S.C. § 119 of Korean Patent Application No. 10-2008-0120193, filed on Nov. 29, 2008, the entire contents of which are hereby incorporated by reference.

### BACKGROUND OF THE INVENTION

The present invention disclosed herein relates to a heterojunction bipolar transistor (HBT) and a method of the heterojunction bipolar transistor, and more particularly, to a heterojunction bipolar transistor having electrode interconnections through plating.

Heterojunction bipolar transistors are ultra-high speed semiconductor active devices that are used in integrated circuits (ICs) of electrical devices such as a transimpedance amplifier (TIA), a limiting amplifier, a modulator driver IC, and multiplexer/demultiplexer (MUX/DeMUX) of ultra wide band communication transmitter/receiver modules. The heterojunction bipolar transistors are also used as power amplifiers for a repeater in infrastructures for mobile communications or mobile communication terminals. Parasitic capacitance of the heterojunction bipolar transistors suppresses ultra-high speed/ultra-high frequency operation.

### SUMMARY OF THE INVENTION

The present invention provides a heterojunction bipolar transistor reducing parasitic capacitance.

The present invention also provides a method of forming a heterojunction bipolar transistor reducing parasitic capacitance.

Embodiments of the present invention provide methods of forming a heterojunction bipolar transistor, the methods including: forming an emitter electrode on an emitter capping pattern, a base electrode on a base pattern, and a collector electrode on a subcollector pattern, the subcollector pattern, the base pattern, an emitter pattern, and the emitter capping pattern being provided to a substrate; patterning a protection insulation layer and a first dummy pattern covering the emitter electrode, the base electrode, and the collector electrode, to expose the emitter electrode, the base electrode, and the collector electrode; forming a second dummy pattern to electrically separate the emitter electrode, the base electrode, and the collector electrode; forming, on the substrate provided with the second dummy pattern, an emitter electrode interconnection connected to the emitter electrode, a base electrode interconnection connected to the base electrode, and a collector electrode interconnection connected to the collector electrode; and removing the first and second dummy patterns.

In some embodiments, the methods may further include forming a metal seed layer on the first dummy pattern and on the exposed emitter electrode, the exposed base electrode, and the exposed collector electrode.

In other embodiments, the forming of the emitter electrode interconnection, the base electrode interconnection, the collector electrode interconnection may include performing an electrolytic plating process.

In still other embodiments, the first dummy pattern may be formed of a photoresist.

In even other embodiments, the second dummy pattern may be formed of a photoresist.

In yet other embodiments, the methods may further include filling spaces, formed by removing the first and second dummy patterns, with a porous material or a material having a low dielectric constant.

In further embodiments, the methods may further include forming a collector pattern on the subcollector pattern, wherein the collector pattern has a sidewall aligned with a sidewall of the base pattern.

In other embodiments of the present invention, heterojunction bipolar transistors include: a subcollector pattern, a base pattern, an emitter pattern, and an emitter capping pattern that are disposed on a substrate; an emitter electrode on the emitter capping pattern; a base electrode on the base pattern; a collector electrode on the subcollector pattern; an emitter electrode interconnection electrically connected to the emitter electrode; a base electrode interconnection electrically connected to the base electrode; and a collector electrode interconnection electrically connected to the collector electrode, wherein a first cavity is disposed between the emitter electrode interconnection and the collector electrode, and a second cavity is disposed between the base electrode interconnection and the collector electrode.

In some embodiments, a third cavity may be disposed between the collector electrode interconnection and the substrate.

In other embodiments, the heterojunction bipolar transistors may further include a protection insulation pattern disposed on sidewalls of the subcollector pattern, the base pattern, the emitter pattern, and the emitter capping pattern.

In still other embodiments, the base electrode interconnection and the emitter electrode interconnection may have uniform thicknesses in a conformal manner.

In even other embodiments, the heterojunction bipolar transistors may further include a metal seed layer under the emitter electrode interconnection and the base electrode interconnection.

In yet other embodiments, the heterojunction bipolar transistors may further include a collector pattern on the subcollector pattern, wherein the collector pattern has a sidewall aligned with a sidewall of the base pattern.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIGS. 1A through 1C are a plan view and cross-sectional views illustrating a heterojunction bipolar transistor according to an embodiment of the present invention;

FIGS. 2A through 2H are views illustrating a method of forming a heterojunction bipolar transistor according to an embodiment of the present invention;

FIGS. 3A, 4A, 5A, 6A and 7A are cross-sectional views taken along line I-I′ of FIG. 1A; and

FIGS. 3B, 4B, 5B, 6B and 7B are cross-sectional views taken along line II-II′ of FIG. 1B.

### DETAILED DESCRIPTION OF PREFERRED EMBODIMENTS

A typical heterojunction bipolar transistor may have a parasitic capacitance between an emitter electrode interconnection and a base electrode, a parasitic capacitance between the emitter electrode interconnection and a collector electrode, and a parasitic capacitance between a base electrode interconnection and the collector electrode. In this case, a protection insulation layer is disposed between the interconnections and the electrodes, and the parasitic capacitances due to the protection insulation layer degrade an alternating current (AC) characteristic.

When there is a sudden height change in a cross-section of a device, an interconnection may be broken. In addition, when there is a sudden height change in a sidewall, the thickness of an interconnection may be decreased. These defects of the interconnections may cause breakage of physical connection and regional resistance heat, so as to degrade stability of the device.

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the figures, the dimensions of layers and regions are exaggerated for clarity of illustration. It will also be understood that when a layer is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

Hereinafter, it will be described about an exemplary embodiment of the present invention in conjunction with the accompanying drawings.

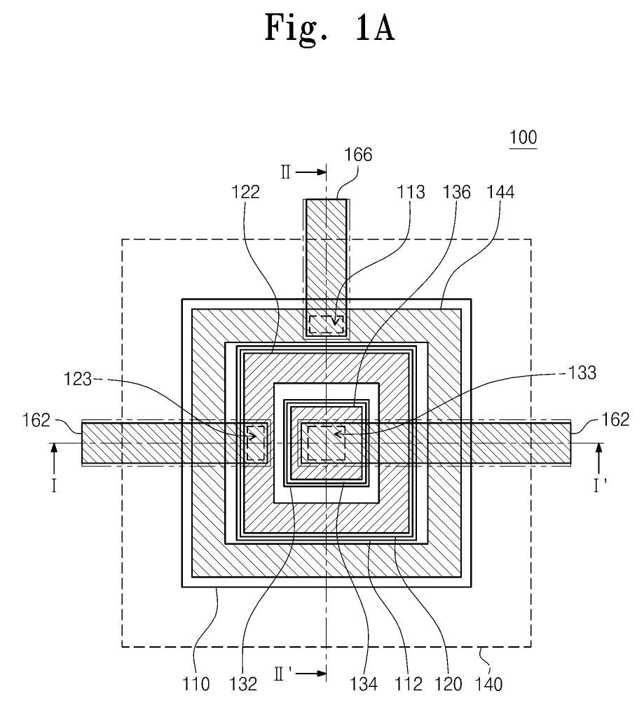

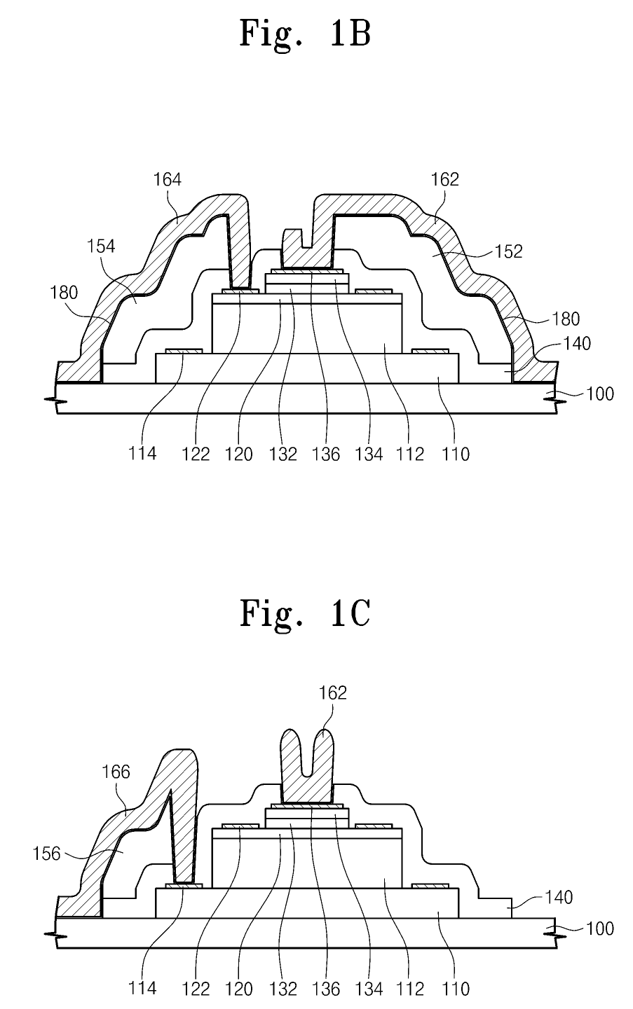

FIGS. 1A through 1C are a plan view and cross-sectional views illustrating a heterojunction bipolar transistor according to one embodiment of the present invention. FIG. 1B is the cross-sectional view taken along line I-I′ of FIG. 1A, and FIG. 1C is a cross-sectional view taken along line II-II′ of FIG. 1A.

Referring to FIG. 1A through 1C, the heterojunction bipolar transistor may include a subcollector pattern 110, a collector pattern 112, a base pattern 120, an emitter pattern 132, and an emitter capping pattern 134 on a substrate 100. An emitter electrode 136 may be disposed on the emitter capping pattern 134, and a base electrode 122 may be disposed on the base pattern 120, and a collector electrode 114 may be disposed on the subcollector pattern 110. An emitter electrode interconnection 162 may be electrically connected to the emitter electrode 136. A base electrode interconnection 164 may be electrically connected to the base electrode 122. A collector electrode interconnection 166 may be electrically connected to the collector electrode 114. A first cavity 152 may be disposed between the emitter electrode interconnection 162 and the collector electrode 114. A second cavity 154 may be disposed between the base electrode interconnection 164 and the collector electrode 114. A third cavity 156 may be disposed between the collector electrode interconnection 166 and the substrate 100.

The subcollector pattern 110, the collector pattern 112, the base pattern 120, the emitter pattern 132, and the emitter capping pattern 134 may be sequentially stacked on the substrate 100. Sidewalls of the collector pattern 112 and the base pattern 120 may be aligned with each other. Sidewalls of the emitter pattern 132 and the emitter capping pattern 134 may be aligned with each other. The emitter pattern 132 and the emitter capping pattern 134 may have a stair shape on the base pattern 120. The emitter electrode 136 may be disposed on the emitter capping pattern 134. The collector pattern 112 and the base pattern 120 may have a stair shape on the subcollector pattern 110.

The substrate 100 may be a GaAs or InP substrate. The emitter capping pattern 134, the base pattern 120, and the subcollector pattern 110 may include an InGaAs-based material. The emitter pattern 132 and the collector pattern 112 may include an InP-based material.

According to another embodiment of the present invention, the emitter capping pattern 134, the base pattern 120, and the subcollector pattern 110 may include an InP-based material. The emitter pattern 132 and the collector pattern 112 may include an InGaAs-based material.

Sidewalls of the subcollector pattern 110, the collector pattern 112, the base pattern 120, the emitter pattern 132, and the emitter capping pattern 134 may be provided with a protection insulation pattern 140. The protection insulation pattern 140 may extend onto the collector electrode 114, the base electrode 122, and the emitter electrode 136. The collector electrode 114, the base electrode 122, and the emitter electrode 136 may include at least one of Ti/Pt/Au, Pt/Ti/Pt/Au, AuGe/Ni/Au, and Au/Ge/Ni/Pd/Au.

The protection insulation pattern 140 may be removed on portions of the emitter electrode 136, the base electrode 122, and the collector electrode 114, so as to form an emitter electrode contact hole 133, a base electrode contact hole 123, and a collector electrode contact hole 113. The protection insulation pattern 140 may include at least one of a silicon oxide layer, a silicon nitride layer, a silicon oxynitride layer, and a material that is lower than the silicon oxide layer in dielectric constant.

The collector electrode contact hole 113 may be filled with the collector electrode interconnection 166. The collector electrode interconnection 166 may be electrically connected to the collector electrode 114. The base electrode contact hole 123 may be filled with the base electrode interconnection 164. The base electrode interconnection 164 may be electrically connected to the base electrode 122. The emitter electrode contact hole 133 may be filled with the emitter electrode interconnection 162. The emitter electrode interconnection 162 may be electrically connected to the emitter electrode 136. The base electrode interconnection 164 and the emitter electrode interconnection 162 may be formed in a conformal manner. The base electrode interconnection 164 and the emitter electrode interconnection 162 may be formed through an electrolytic plating process.

The first through third cavities 152, 154, and 156 may be formed by removing a first dummy pattern (not shown). The first through third cavities 152, 154, and 156 may be filled with a porous material or a material having a low dielectric constant. The lower portion of the emitter electrode interconnection 162 and the lower portion of the base electrode interconnection 164 may be provided with a metal seed layer 180 that may be a seed layer of the electrolytic plating process.

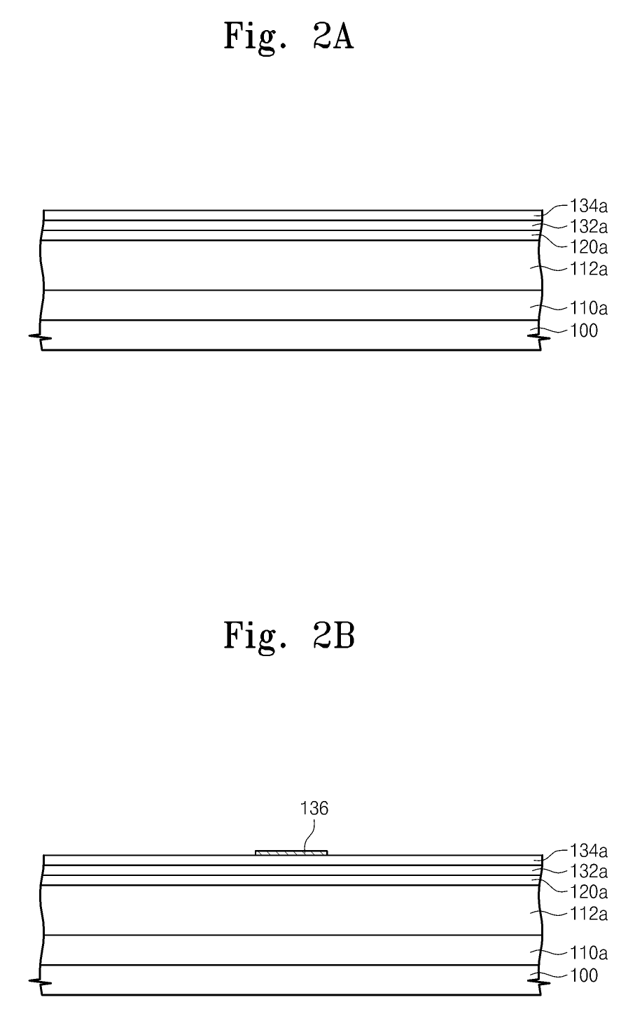

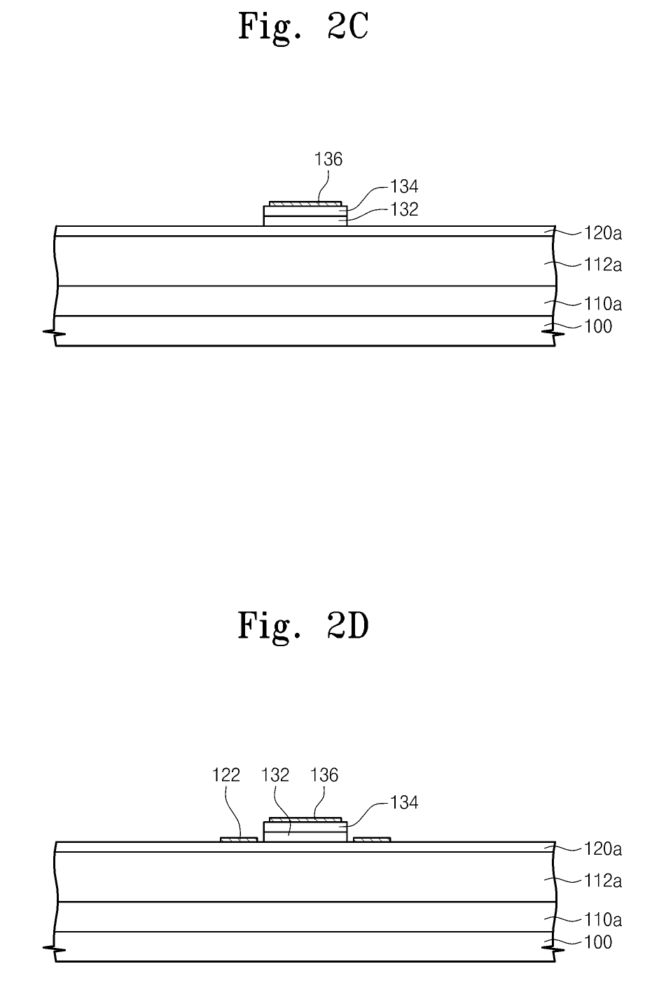

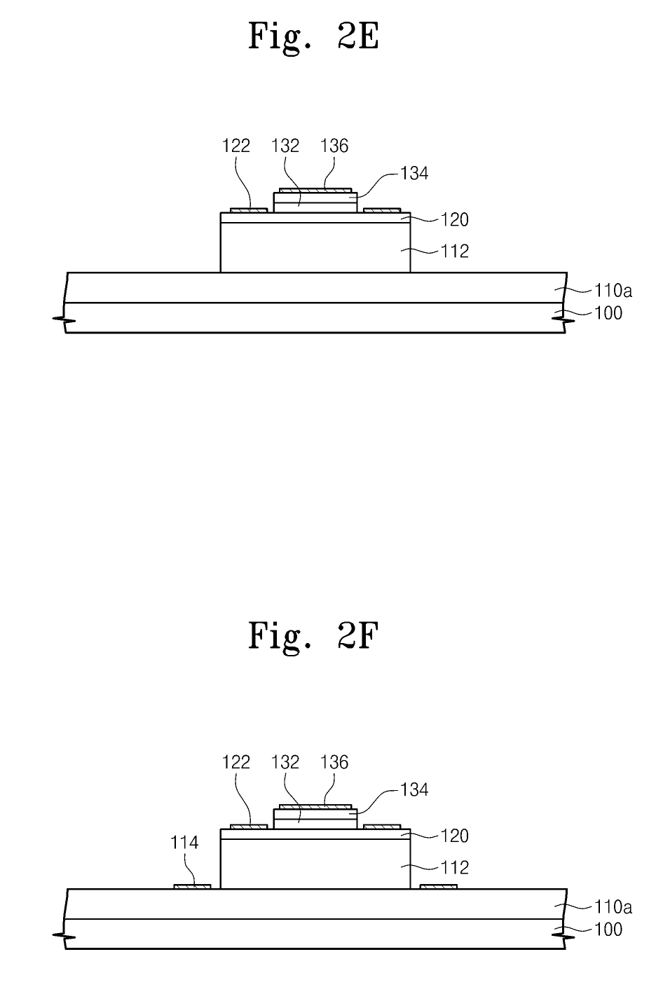

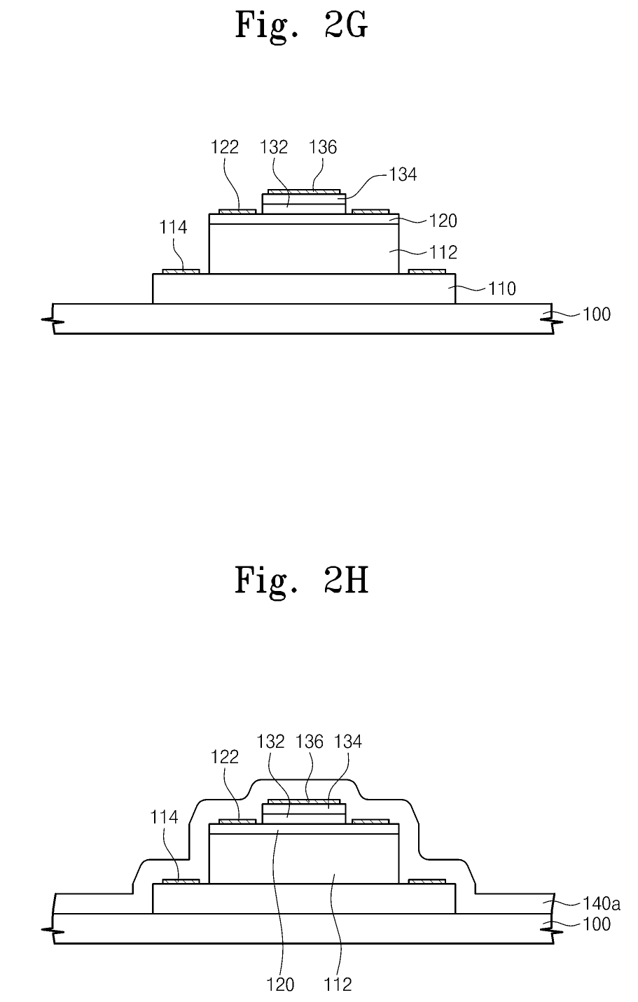

FIGS. 2A through 2H are views illustrating the method of forming the heterojunction bipolar transistor according to an embodiment of the present invention. FIGS. 2A through 2H are cross-sectional views taken along the line I-I′ of FIG. 1A.

Referring to FIG. 2A, to form the heterojunction bipolar transistor according to the current embodiment, a subcollector layer 110a, a collector layer 112a, a base layer 120a, an emitter layer 132a, and an emitter capping layer 134a may be sequentially stacked on the substrate 100. The subcollector layer 110a, the collector layer 112a, the base layer 120a, the emitter layer 132a, and the emitter capping layer 134a may be epitaxial layers that are sequentially grown. The substrate 100 may be a GaAS or InP substrate. The emitter capping layer 134a, the base layer 120a, and the subcollector layer 110a may include an InGaAs-based material. The emitter layer 132a and the collector layer 112a may include an InP-based material.

Referring to FIG. 2B, the emitter electrode 136 may be formed on the emitter capping layer 134a. A photoresist pattern (not shown), having a negative slope, may be formed on the emitter capping layer 134a using an image reversal lithography method. An emitter metal layer (not shown) may be formed on the photoresist pattern. The emitter metal layer may be formed through an evaporation process or sputtering process. The photoresist pattern may be removed using a lift off process to form the emitter electrode 136. The emitter electrode 136 may include Ti/Pt/Au, Pt/Ti/Pt/Au, AuGe/Ni/Au, or Au/Ge/Ni/Pd/Au.

Referring to FIG. 2C, a photoresist pattern (not shown) may be formed on the emitter electrode 136 and the emitter capping layer 134a. The emitter capping layer 134a and the emitter layer 132a are etched using the photoresist pattern as an etching mask, so as to expose the base layer 120a and form the emitter capping pattern 134 and the emitter pattern 132. The etching may be a wet or dry etching. A process gas of the dry etching process may contain at least one of BCl₃, Cl₂, CH₄, CHF₃, CCl₄, and SF₆. A capacitively coupled plasma apparatus or an inductively coupled plasma apparatus may be used for the dry etching process. An etchant of the wet etching process may contain at least one of H₃PO₄, HCl, NH₄OH, and H₂O₂. The emitter capping layer 134a, including an InGaAs-based material, may be etched using an etchant including H₃PO₄, H₂O₂, and H₂O. The emitter layer 132a, including an InP-based material, may be etched using an etchant including HCl and H₃PO₄. The photoresist pattern may be selectively removed.

Referring to FIG. 2D, the base electrode 122 may be formed on the base layer 120a. A photoresist pattern (not shown), having a negative slope, may be formed on the base layer 120a using the image reversal lithography method. A base metal layer may be formed on the photoresist pattern. The photoresist pattern may be removed using a lift off process to form the base electrode 122. The base electrode 122 may include Ti/Pt/Au, Pt/Ti/Pt/Au, AuGe/Ni/Au, or Au/Ge/Ni/Pd/Au. The photoresist pattern may be selectively removed.

Referring to FIG. 2E, a photoresist pattern (not shown) may be formed on the base electrode 122 and the emitter electrode 136. The base layer 120a and the collector layer 112a may be etched using the photoresist pattern as an etching mask, so as to expose the subcollector layer 110a and form the base pattern 120 and the collector pattern 112. The etching may be a wet or dry etching. A process gas of the dry etching process may include at least one of BCl₃, Cl₂, CH₄, CHF₃, CCl₄, and SF₆. A capacitively coupled plasma apparatus or an inductively coupled plasma apparatus may be used for the dry etching process. An etchant of the wet etching process may include at least one of H₃PO₄, HCl, NH₄OH, and H₂O₂. The base pattern 120, including an InGaAs-based material, may be etched using an etchant containing H₃PO₄, H₂O₂, and H₂O. The collector layer 112a, including an InP-based material, may be etched using an etchant containing HCl and H₃PO₄. The photoresist pattern may be selectively removed.

Referring to FIG. 2F, the collector electrode 114 may be formed on the subcollector layer 110a. A photoresist pattern (not shown), having a negative slope, may be formed on the subcollector layer 110a using the image reversal lithography method. A collector metal layer may be formed on the photoresist pattern. The photoresist pattern may be removed using a lift off process to form the collector electrode 114. The collector electrode 114 may include Ti/Pt/Au, Pt/Ti/Pt/Au, AuGe/Ni/Au, or Au/Ge/Ni/Pd/Au.

Referring to FIG. 2G, a photoresist pattern (not shown) may be formed on the collector electrode 114, the base electrode 122, and the emitter electrode 136. The subcollector layer 110a may be etched using the photoresist pattern as an etching mask, so as to expose the substrate 100 and form the subcollector pattern 110. The etching may be a wet or dry etching. A process gas of the dry etching process may contain at least one of BCl₃, Cl₂, CH₄, CHF₃, CCl₄, and SF₆. A capacitively coupled plasma apparatus or an inductively coupled plasma apparatus may be used for the dry etching process. An etchant of the wet etching process may contain at least one of H₃PO₄, HCl, NH₄OH, and H₂O₂. The subcollector layer 110a, including an InGaAs-based material, may be etched using an etchant containing H₃PO₄, H₂O₂, and H₂O. The photoresist pattern may be selectively removed.

Referring to FIG. 2H, a protection insulation layer 140a may be formed on the entire surface of the substrate 100 provided with the emitter electrode 136, the base electrode 122, and the collector electrode 114. The protection insulation layer 140a may include at least one of a silicon oxide layer, a silicon nitride layer, and a silicon oxynitride layer. The silicon nitride layer may be deposited using reaction gas such as SiH₄ and NH₃ according to a Plasma Enhanced Chemical Vapor Deposition (PECVD) method. The protection insulation layer 140a may be formed in a conformal manner on the substrate 100.

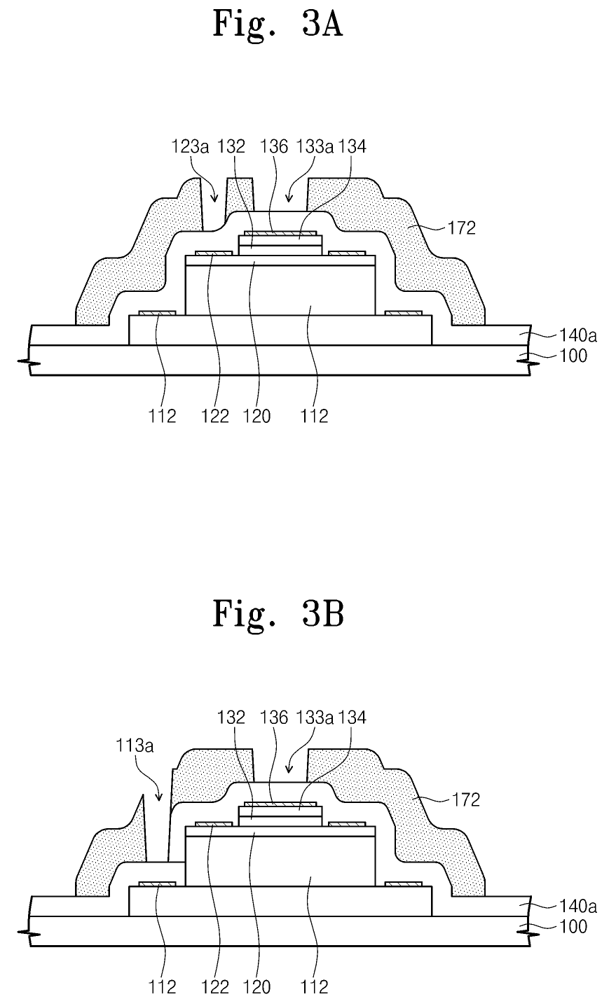

FIGS. 3A and 3B are views illustrating the method of forming the heterojunction bipolar transistor according to an embodiment of the present invention. FIG. 3A is a cross-sectional view taken along the line I-I′ of FIG. 1A, and FIG. 3B is a cross-sectional view taken along the line II-II′ of FIG. 1A.

Referring to FIGS. 3A and 3B, a first dummy pattern 172 may be formed on the substrate 100. The first dummy pattern 172 may be partially removed on the emitter electrode 136, the base electrode 122, and the collector electrode 114. The first dummy pattern 172 may be removed from the substrate 100 except for a device region (not shown) provided with the heterojunction bipolar transistor. The first dummy pattern 172 may include at least one of photoresist, dielectric, polyimide, and acryl. The first dummy pattern 172 may include a preliminary emitter contact hole 133a, a preliminary base contact hole 123a, and a preliminary collector contact hole 113a. The preliminary emitter contact hole 133a may be disposed on the emitter electrode 136. The preliminary base contact hole 123a may be disposed on the base electrode 122. The preliminary collector contact hole 113a may be disposed on the collector electrode 114.

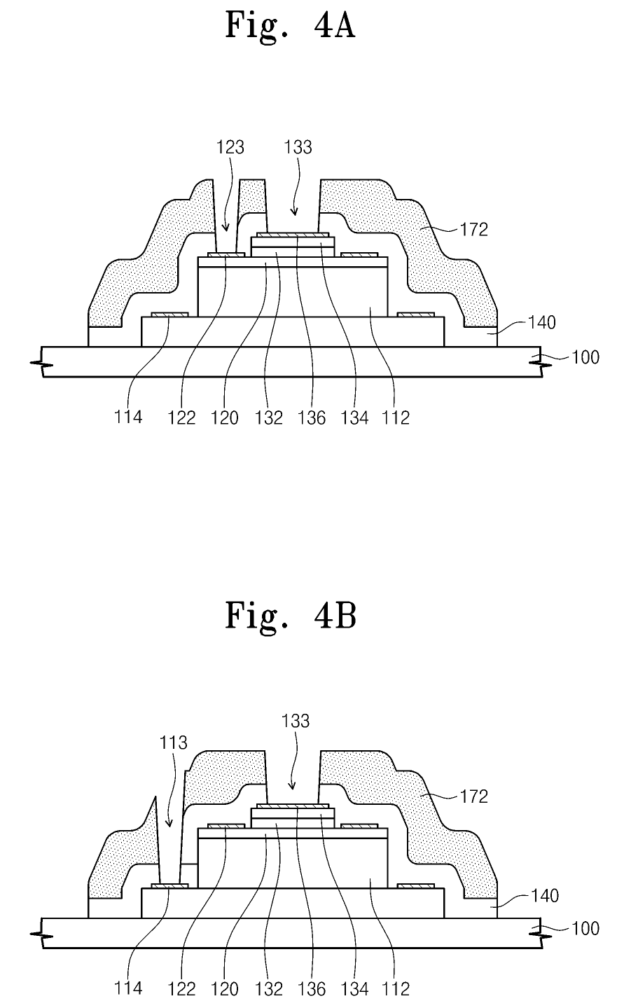

FIGS. 4A and 4B are views illustrating the method of forming the heterojunction bipolar transistor according to an embodiment of the present invention. FIG. 4A is a cross-sectional view taken along the line I-I′ of FIG. 1A, and FIG. 4B is a cross-sectional view taken along the line II-II′ of FIG. 1A.

Referring to FIGS. 4A and 4B, the protection insulation layer 140a may be patterned using the first dummy pattern 172 as an etching mask to form the emitter electrode contact hole 133, the base electrode contact hole 123, and the collector electrode contact hole 113. The emitter electrode 136 may be exposed through the emitter electrode contact hole 133. The base electrode 122 may be exposed through the base electrode contact hole 123. The collector electrode 114 may be exposed through the collector electrode contact hole 113.

The protection insulation layer 140a may be patterned using the first dummy pattern 172 as an etching mask to form the protection insulation pattern 140. The patterning may be dry etching using a CF-based reaction gas. The patterning may be anisotropy etching, so that the cross-section of the protection insulation layer 140a has a positive slope with respect to the substrate 100.

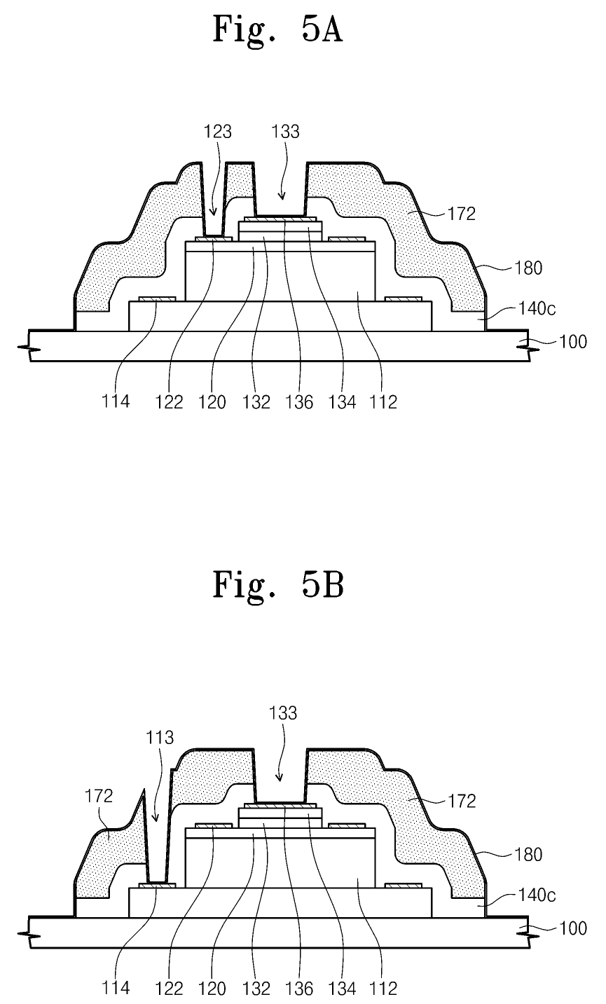

FIGS. 5A and 5B are views illustrating the method of forming the heterojunction bipolar transistor according to an embodiment of the present invention. FIG. 5A is a cross-sectional view taken along the line I-I′ of FIG. 1A, and FIG. 5B is a cross-sectional view taken along the line II-II′ of FIG. 1A.

Referring to FIGS. 5A and 5B, the metal seed layer 180, used for electrical connection in a subsequent plating process, may be formed on the entire surface of the substrate 100. The metal seed layer 180 may have a stack structure of Ti/Ni/Au. Ti of the metal seed layer 180 may have a thickness of about 2 to 3 nm. Ni of the metal seed layer 180 may have a thickness of about 7 to 20 nm. Au of the metal seed layer 180 may have a thickness of about 1.5 to 3 nm. Since the metal seed layer 180 is thin, the metal seed layer 180 can be easily removed in a subsequent process of removing the first dummy pattern 172.

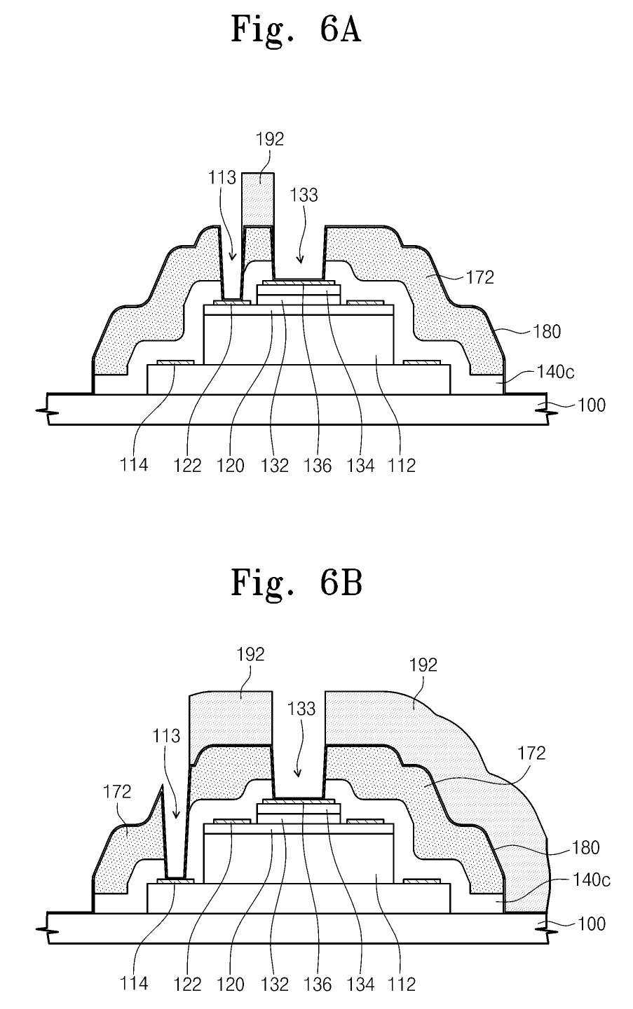

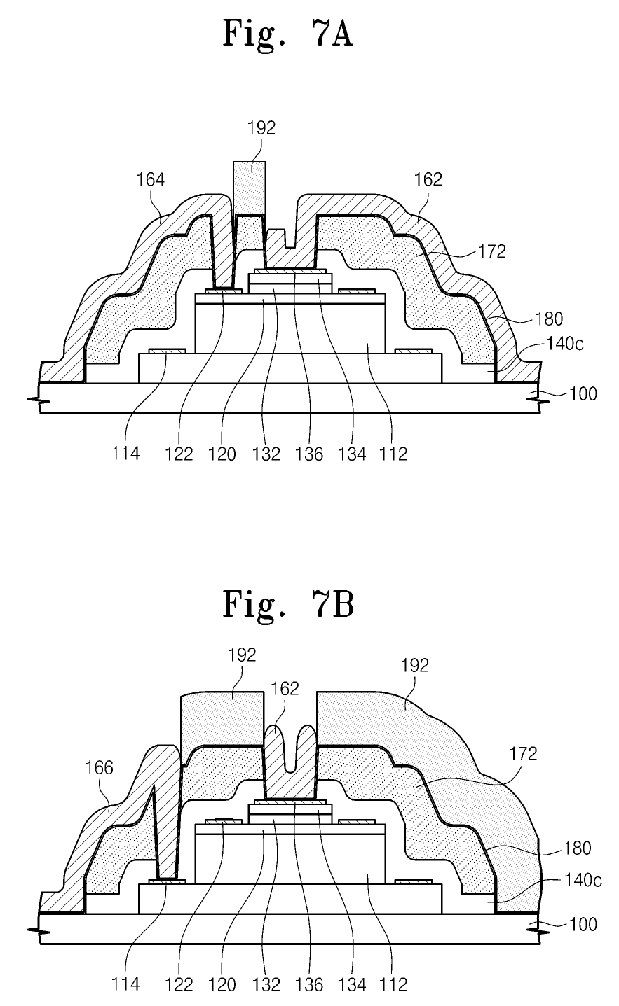

FIGS. 6A and 6B are views illustrating the method of forming the heterojunction bipolar transistor according to an embodiment of the present invention. FIG. 6A is a cross-sectional view taken along the line I-I′ of FIG. 1A, and FIG. 7B is a cross-sectional view taken along the line II-II′ of FIG. 1A.

Referring to FIGS. 6A and 6B, a second dummy pattern 192 may be formed on the substrate 100 with the metal seed layer 180 and define a region that will not be plated. Electrode interconnections (not shown) may be disposed in a region without the second dummy pattern 192. The second dummy pattern 192 may include at least one of photoresist, dielectric, polyimide, and acryl, and have a larger thickness than that of the first dummy pattern 172. For example, the first dummy pattern 172 may have a thickness of about 1 to 1.5 μm, and the second dummy pattern 192 may have a thickness of about 3 to 4 μm.

FIGS. 7A and 7B are views illustrating the method of forming the heterojunction bipolar transistor according to an embodiment of the present invention. FIG. 7A is a cross-sectional view taken along the line I-I′ of FIG. 1A, and FIG. 7B is a cross-sectional view taken along the line II-II′ of FIG. 1A.

Referring to FIGS. 7A and 7B, the emitter electrode interconnection 162, the base electrode interconnection 164, and the collector electrode interconnection 166 may be formed on the substrate 100 with the second dummy pattern 192 by using an electrolytic plating process. The electrode interconnections 162, 164, and 166 may be formed in regions where the second dummy pattern 192 is not formed. Although the electrode interconnections 162, 164, and 166 have different heights, the electrode interconnections 162, 164, and 166 may conform with the exposed metal seed layer 180. It makes it possible to prevent the cutting or slimming of the electrode interconnections 162, 164, and 166 due to the height differences on the sidewall of the collector pattern 112.

Referring again to FIGS. 1B and 1C, the first dummy pattern 172 and the second dummy pattern 192 may be removed using a selective wet etching process to form the first cavity 152, the second cavity 154, and the third cavity 156. The first cavity 152, the second cavity 154, and the third cavity 156 may be vacant spaces. The first cavity 152 may be disposed between the emitter electrode interconnection 162 and the collector electrode 114.

The second cavity 154 may be disposed between the base electrode interconnection 164 and the collector electrode 114. The third cavity 156 may be disposed between the collector electrode interconnection 166 and the substrate 100. Since the metal seed layer 180 under the second dummy pattern 192 is thin, the metal seed layer 180 is easily removed by a little damage according to, e.g. an acetone spray method.

Therefore, the first cavity 152 provides a relatively low parasitic capacitance between an emitter and a collector, and the second cavity 154 provides a relatively low parasitic capacitance between a base and the collector, and the third cavity 156 provides a relatively low parasitic capacitance between a substrate and the collector.

According to another embodiment of the present invention, the first cavity 152, the second cavity 154, and the third cavity 156 may be filled with a porous material or a material having a low dielectric constant.

The heterojunction bipolar transistor according to the embodiment of the present invention reduces parasitic capacitances due to electrode interconnections, thereby improving the speed and AC characteristic thereof.

The heterojunction bipolar transistor according to one embodiment of the present invention include the electrode interconnections of the emitter electrode, the base electrode, and the collector electrode, in which the electrode interconnections may be formed in an air bridge shape by using the plating process. Accordingly, vacant spaces are secured between the electrodes and the interconnections. Also, the parasitic capacitances between the emitter and the base, and between the emitter and the collector, and between the base and the collector are reduced so as to improve the AC characteristic of the device.

In addition, the heterojunction bipolar transistor according to one embodiment of the present invention may have the conformal electrode interconnections through the plating process. Thus, slimming or cutting of the electrode interconnections is prevented to improve stability and reliability of the heterojunction bipolar transistor.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of forming a heterojunction bipolar transistor, the method comprising:
forming an emitter electrode on an emitter capping pattern, a base electrode on a base pattern, and a collector electrode on a subcollector pattern, the subcollector pattern, the base pattern, an emitter pattern, and the emitter capping pattern being provided to a substrate;
patterning a protection insulation layer and a first dummy pattern covering the emitter electrode, the base electrode, and the collector electrode, to expose the emitter electrode, the base electrode, and the collector electrode;
forming a second dummy pattern to electrically separate the emitter electrode, the base electrode, and the collector electrode;
forming, on the substrate provided with the second dummy pattern, an emitter electrode interconnection connected to the emitter electrode, a base electrode interconnection connected to the base electrode, and a collector electrode interconnection connected to the collector electrode; and
removing the first and second dummy patterns.

2. The method of claim 1, further comprising forming a metal seed layer on the first dummy pattern and on the exposed emitter electrode, the exposed base electrode, and the exposed collector electrode.

3. The method of claim 1, wherein the forming of the emitter electrode interconnection, the base electrode interconnection, the collector electrode interconnection comprises performing an electrolytic plating process.

4. The method of claim 1, wherein the first dummy pattern is formed of a photoresist.

5. The method of claim 1, wherein the second dummy pattern is formed of a photoresist.

6. The method of claim 1, further comprising filling spaces, formed by removing the first and second dummy patterns, with a porous material or a material having a low dielectric constant.

7. The method of claim 1, further comprising forming a collector pattern on the subcollector pattern,
wherein the collector pattern has a sidewall aligned with a sidewall of the base pattern.

8. A heterojunction bipolar transistor comprising:
a subcollector pattern, a base pattern, an emitter pattern, and an emitter capping pattern that are disposed on a substrate;
an emitter electrode on the emitter capping pattern;
a base electrode on the base pattern;
a collector electrode on the subcollector pattern;
an emitter electrode interconnection electrically connected to the emitter electrode;
a base electrode interconnection electrically connected to the base electrode; and
a collector electrode interconnection electrically connected to the collector electrode,
wherein a first cavity is disposed between the emitter electrode interconnection and the collector electrode, and a second cavity is disposed between the base electrode interconnection and the collector electrode.

9. The heterojunction bipolar transistor of claim 8, wherein a third cavity is disposed between the collector electrode interconnection and the substrate.

10. The heterojunction bipolar transistor of claim 8, further comprising a protection insulation pattern disposed on sidewalls of the subcollector pattern, the base pattern, the emitter pattern, and the emitter capping pattern.

11. The heterojunction bipolar transistor of claim 8, wherein the base electrode interconnection and the emitter electrode interconnection have uniform thicknesses in a conformal manner.

12. The heterojunction bipolar transistor of claim 8, further comprising a metal seed layer under the emitter electrode interconnection and the base electrode interconnection.

13. The heterojunction bipolar transistor of claim 8, further comprising a collector pattern on the subcollector pattern,
wherein the collector pattern has a sidewall aligned with a sidewall of the base pattern.
